(19) United States
(12) Patent Application Publication
(10) Pub. No.: US 2026/0319377 A1
(43) Pub. Date: Oct. 15, 2026

(54) Systems, Methods, And Devices For Coherence Control In Microscopes

(71) Applicant: EUV Tech, Inc., Martinez, CA (US)

(72) Inventor: Patrick Naulleau, Pleasant Hill, CA (US)

(21) Appl. No.: 19/174,573

(22) Filed: Apr. 9, 2025

(51) Int. Cl. G03F 7/00

(52) U.S. Cl. CPC G03F 7/70316; G03F 7/70033; G03F 7/70091

(57) ABSTRACT

Systems, methods, and devices disclosed herein provide coherence control for light sources in various operational environments. Systems include a light source configured to generate a first optical output, and an optical device configured to receive the first optical output. The optical device includes a spatial light modulator configured to receive the first optical output from the light source, wherein the spatial light modulator comprises a micromechanical device configured to generate a second optical output based, at least in part, on the first optical output and a plurality of coherence parameters defining a plurality of angles of light to be included in the second optical output. The optical device also includes an imaging optic configured to receive the second optical output from the spatial light modulator, and further configured to generate a third optical output provided to an imaging target.

### FIELD OF TECHNOLOGY

This patent application relates generally to lithography, and more specifically to coherence control for optics used with microscopy.

### BACKGROUND

Lithography techniques may use one or more patterning techniques to apply a pattern to a lithography target. For example, photolithography may use light to induce changes in the lithography target that may subsequently be used to etch a pattern in the lithography target. The pattern itself may be represented in a photomask which may be used in combination with a resist that coats the lithography target itself. Examination of such photomasks and resists may be performed using optics to generate images of such photomasks and resists to ensure that they may be used in the lithography process. However, conventional techniques for performing such imaging and examination remain limited because they are constrained in their ability to control coherence of light used in such imaging operations.

### SUMMARY

In some embodiments, techniques described herein relate to a system for coherence control for lithography. In some aspects, the techniques described herein relate to a system including: a light source configured to generate a first optical output; and an optical device configured to receive the first optical output, the optical device including: a spatial light modulator configured to receive the first optical output from the light source, wherein the spatial light modulator includes a micromechanical device configured to generate a second optical output based, at least in part, on the first optical output and a plurality of coherence parameters defining a plurality of angles of light to be included in the second optical output; and an imaging optic configured to receive the second optical output from the spatial light modulator, and further configured to generate a third optical output provided to an imaging target.

In some embodiments, the techniques described herein relate to a system, wherein the plurality of coherence parameters identifies a first range of angles of light to be included in the second optical output, and wherein the plurality of coherence parameters further identifies a second range of angles of light to be removed from the second optical output. In some embodiments, the techniques described herein relate to a system, wherein the micromechanical device includes a plurality of micromechanical mirrors configured to be actuated based, at least in part, on the plurality of coherence parameters.

In some embodiments, the techniques described herein relate to a system, wherein each of the plurality of micromechanical mirrors includes a coating configured to reflect extreme ultraviolet (EUV) light. In some embodiments, the techniques described herein relate to a system, wherein the micromechanical device includes a plurality of micromechanical shutters configured to be actuated based, at least in part, on the plurality of coherence parameters. In some embodiments, the techniques described herein relate to a system, wherein each of the plurality of micromechanical shutters is configured to optically gate light provided to a corresponding optical pathway configured to transmit extreme ultraviolet (EUV) light.

In some embodiments, the techniques described herein relate to a system, wherein the light source is a brightness-limited extreme ultraviolet (EUV) light source. In some embodiments, the techniques described herein relate to a system, wherein the light source has a first etendue that is larger than a second etendue of the optical device. In some embodiments, the techniques described herein relate to a system, wherein the plurality of coherence parameters is determined based, at least in part, on an input received via a client machine associated with a user.

In some embodiments, the techniques described herein relate to a device including: a spatial light modulator configured to receive a first optical output from a light source, wherein the spatial light modulator includes a micromechanical unit configured to generate a second optical output based, at least in part, on the first optical output and a plurality of coherence parameters defining a plurality of angles of light to be included in the second optical output; and an imaging optic configured to receive the second optical output from the spatial light modulator, and further configured to generate a third optical output provided to an imaging target.

In some embodiments, the techniques described herein relate to a device, wherein the plurality of coherence parameters identifies a first range of angles of light to be included in the second optical output, and wherein the plurality of coherence parameters further identifies a second range of angles of light to be removed from the second optical output. In some embodiments, the techniques described herein relate to a device, wherein the micromechanical unit includes a plurality of micromechanical mirrors configured to be actuated based, at least in part, on the plurality of coherence parameters.

In some embodiments, the techniques described herein relate to a device, wherein each of the plurality of micromechanical mirrors includes a coating configured to reflect extreme ultraviolet (EUV) light. In some embodiments, the techniques described herein relate to a device, wherein the micromechanical unit includes a plurality of micromechanical shutters configured to be actuated based, at least in part, on the plurality of coherence parameters. In some embodiments, the techniques described herein relate to a device, wherein each of the plurality of micromechanical shutters is configured to optically gate light provided to a corresponding optical pathway configured to transmit extreme ultraviolet (EUV) light.

In some embodiments, the techniques described herein relate to a method including: receiving a first optical output from a light source; generating, using a spatial light modulator, a second optical output, wherein the second optical output is generated by a micromechanical device included in the spatial light modulator and based, at least in part, on the first optical output and a plurality of coherence parameters defining a plurality of angles of light to be included in the second optical output; providing the second optical output to imaging optic; and generating, using the imaging optic, a third optical output being capable of being provided to an imaging target.

In some embodiments, the techniques described herein relate to a method, wherein the plurality of coherence parameters identifies a first range of angles of light to be included in the second optical output, and wherein the plurality of coherence parameters further identifies a second range of angles of light to be removed from the second optical output. In some embodiments, the techniques described herein relate to a method, wherein the second optical output is generated by a plurality of micromechanical mirrors included in the micromechanical device, and based, at least in part, on the plurality of coherence parameters. In some embodiments, the techniques described herein relate to a method, wherein the second optical output is generated by a plurality of micromechanical shutters included in the micromechanical device, and based, at least in part, on the plurality of coherence parameters. In some embodiments, the techniques described herein relate to a method, wherein the light source is a brightness-limited extreme ultraviolet (EUV) light source. These and other embodiments are described further below with reference to the figures.

### BRIEF DESCRIPTION OF THE DRAWINGS

The included drawings are for illustrative purposes and serve only to provide examples of possible structures and operations for the disclosed inventive systems, apparatus, methods, and devices for coherence control for lithography. These drawings in no way limit any changes in form and detail that may be made by one skilled in the art without departing from the spirit and scope of the disclosed implementations.

FIG. 1 illustrates an example of a system for coherence control, configured in accordance with some embodiments.

FIG. 2 illustrates an example of a device for coherence control, configured in accordance with some embodiments.

FIG. 3 illustrates another example of a device for coherence control, configured in accordance with some embodiments.

FIG. 4 illustrates an additional example of a device for coherence control, configured in accordance with some embodiments.

FIG. 5 illustrates another example of a device for coherence control, configured in accordance with some embodiments.

FIG. 6 illustrates an example of a micromechanical shutter unit, configured in accordance with some embodiments.

FIG. 7 illustrates an example of a method for coherence control, performed in accordance with some embodiments.

FIG. 8 illustrates another example of a method for coherence control, performed in accordance with some embodiments.

### DETAILED DESCRIPTION

In various embodiments, photomasks may be used during lithography operations applied to lithography targets, such as silicon wafers. Moreover, illumination and imaging techniques may be used for imaging components used in lithography operations, such as photomasks. For example, a light source may be used to generate light that is used to illuminate a photomask and lithography target, and reflected light may be received at an imaging device to generate an image. Such images may be used to assess performance features of a component, such as a photomask, and determine if such components are of a sufficient quality for a manufacturing process to proceed. In such imaging operations, coherence control over the light being used enables improved accuracy in assessment of the target components resulting from increased uniformity in the light used for such imaging and decreased variance in the image itself due to a decreased nonuniformity of such illumination.

Conventional techniques for generating light used in microscopy operations in extreme ultraviolet (EUV) contexts remain limited because they are limited in their ability to control coherence of light used in imaging and microscopy operations. More specifically, they may rely on the use of a set of fixed apertures. However, such approaches are limited in a number of different coherence control settings that they may provide, and are also not well suited for systems using brightness-limited light sources due to the use of such apertures that block light. Accordingly, conventional techniques are not able to effectively provide a range of coherence control capabilities and also in a manner compatible with brightness-limited light sources.

Embodiments disclosed herein provide systems, devices, and methods that control coherence parameters of light in a manner that provides a wide range of coherence control capabilities, and also is compatible with brightness-limited light sources. In various embodiments, a brightness-limited light source may be a light source that has an etendue that is larger than an etendue of the imaging optics. As will be discussed in greater detail below, a spatial light modulator may be included within optics used for such imaging and microscopy operations. The spatial light modulator may include a micromirror array, and may be configured to implement various coherence parameters based on a received input from, for example, a computer system or computing device. Accordingly, the spatial light modulator may be used to dynamically implement a wide range of coherence parameters based, at least in part, on a range of motion provided by the mirrors of the micromirror array. For example, a micromirror unit including millions of micromirrors may be used to support millions of possible optical configurations and associated coherence parameters. In this way, a spatial light modulator may be configured to increase a range of available coherence parameter settings from tens of coherence parameter settings to thousands and, in some embodiments, millions of available coherence parameter settings. Moreover, such coherence parameters may be implemented in a manner that is compatible with brightness-limited light sources.

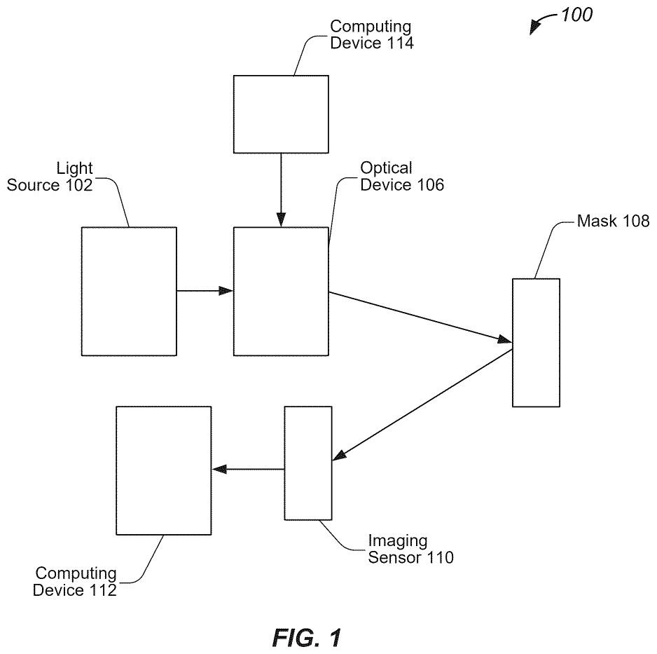

FIG. 1 illustrates an example of a system for coherence control, configured in accordance with some embodiments. As similarly discussed above, embodiments disclosed herein enable the implementation of a large range of coherence parameters used to control coherence of light received from a light source, which may be a brightness limited light source. Accordingly, a system, such as system 100, may be configured to provide such coherence control to enable highly flexible and dynamic coherence control that is compatible with brightness-limited components.

In various embodiments, system 100 includes light source 102 which is configured to generate light used for imaging, microscopy, and lithography operations described herein. In various embodiments, light source 102 is configured to generate EUV light. In various embodiments, light source 102 may be configured to generate EUV light based on the generation of a laser produced plasma. In some embodiments, light source 102 is configured to generate EUV light based on the generation of discharge produced plasma. It will be appreciated that any suitable technique for generating EUV light is contemplated and disclosed herein. Moreover, while various embodiments describe the use of EUV light, any suitable wavelengths of light may be used for imaging, microscopy, and lithography applications, for example soft-x-ray wavelengths.

System 100 additionally includes optical device 106 which is configured to receive an optical output from light source 102. As will be discussed in greater detail below, optical device 106 may be configured to implement one or more coherence parameters to control coherence properties of the light generated by light source 102. More specifically, optical device 106 may include a micromechanical unit, which may be a device such as a micromirror array, that includes computer-controlled and actuated micromirrors capable of changing their position and angle relative to light source 102. Accordingly, such micromirrors may be controlled and positioned dynamically, to select and implement a designated set of coherence parameters, and generate an optical output based on the implementation of such coherence parameters. In various embodiments, the micromechanical device may include micromechanical shutters that are configured to provide optical gating of light based on an amount of actuation of such micromechanical shutters.

In various embodiments, positions of the micromechanical shutters are configured in a plane such that each position is mapped to a particular angle space based on a relationship between the position of the light source and that position. Accordingly, a two-dimensional mapping of shutters may correspond to selected ranges of angles based on a known relationship between the positions of such shutters and their corresponding angles determined based on the geometry and relationship to the position of the light source, as discussed above. In this way, a local attenuation map used to determine a configuration of the micromechanical shutters may select particular ranges of angles because such positions of such shutters have been mapped to an angle space based on known geometrical relationship between light source 102 and the micromechanical device.

As disclosed herein, such coherence parameters may identify a first designated set of angles that are reflected and passed by the micromirror device to a downstream component, such as an imaging optic. The coherence parameters may also identify a second designated set of angles that are discarded and are not passed by the micromirror device to the downstream component, such as the imaging optic. As discussed above, such coherence parameters may be implemented via actuation of mirrors or shutters. As will be discussed in greater detail below, the imaging optic may provide an optical output that is used for imaging operations.

In various embodiments, optical device 106 may be included in a housing that is configured to provide mechanical and structural support for optical device 106 and components of optical device 106. For example, such a housing may provide structural and mechanical support for a micromirror device as well as an imaging optic. The housing may also provide a communications port or other communications interface allowing communication between the micromirror device and a computing device, such as computing device 114. In various embodiments, computing device 114 includes components, such as a processor and memory, that are configured to execute a control application for optical device 106. In this way, an entity, such as a user or administrator, may provide an input to computing device 114 via a user interface, and such an input may be used to select and apply coherence parameters via optical device 106, and a micromirror device included in optical device 106.

In various embodiments, system 100 additionally includes a lithography target, such as mask 108. As similarly discussed above, mask 108 may be disposed on a substrate, such as a quartz plate, that will undergo lithography operations. As shown in FIG. 1, the optical output of optical device 106 may be provided to mask 108 with the coherence control provided by optical device 106. The optical output may reflect off of mask 108, and may be received at an imaging device, such as imaging sensor 110. In various embodiments, imaging sensor 110 may be any suitable imaging sensor capable of capturing images of mask 108. For example, imaging sensor may include a charge-coupled device (CCD) sensor or a complementary metal-oxide-semiconductor (CMOS) sensor configured to capture a digital image of mask 108, and provide such imaging data to a computing device, such as computing device 112.

In various embodiments, computing device 112 is configured to include components, such as a processor and memory, configured to perform image processing operations on the received imaging data to render an image of mask 108. In various embodiments, computing device 112 and computing device 114 may be implemented as separate stand-alone computing devices or systems, or they may be implemented in one computing system. For example, one of computing device 112 and computing device 114 may be configured to perform both image processing operations as well control of optical device 106.

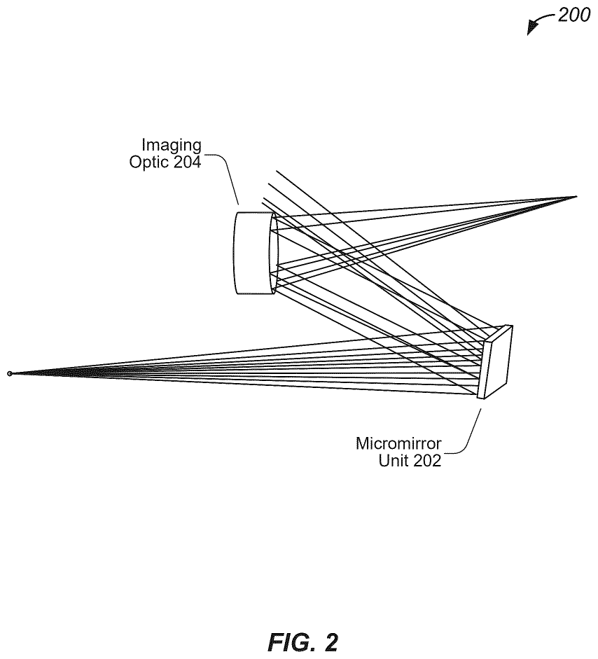

FIG. 2 illustrates an example of a device for coherence control, configured in accordance with some embodiments. As similarly discussed above, embodiments disclosed herein enable the implementation of a large range of coherence parameters used to control coherence of light received from a light source, which may be a brightness limited light source. Accordingly, a device, such as device 200, may include an embedded spatial light modulator within an illumination system that is configured to implement coherence parameters to provide coherence control for illumination provided in microscopy and lithography operations.

In various embodiments, device 200 includes a spatial light modulator, such as micromirror unit 202 which may include micromirrors capable of actuation via one or more inputs received from a computing device or system. For example, micromirror unit 202 may be a micromirror array similar to those used in digital light processing (DLP) projectors that have digital micromirror devices (DMDs). Accordingly, micromirror unit 202 may include any suitable micromirror array capable of actuation of micromirrors. However, such micromirror arrays may be configured for EUV lithography applications. More specifically, the mirrors of micromirror unit 202 may be coated in a reflective material configured to reflect a range of wavelengths used for EUV microscopy and lithography operations.

In various embodiments, micromirror unit 202 is configured to locally attenuate or extinguish light received from a light source. As shown in FIG. 2, such a light source may present as a point source of light provided to micromirror unit 202. In one example, micromirror unit 202 may be positioned in a plane that is conjugate to the target object plane. Micromirrors of micromirror unit 202 may be selectively actuated to locally attenuate the received beam of light thus providing the ability to locally control the illumination spatial frequencies of the received light and its corresponding coherence properties. For example, micromirror unit 202 may be configured to locally deflect the received beam of light to steer it away from imaging optic 204, discussed in greater detail below. More specifically, mirrors included in micromirror unit 202 may each apply an angle of deflection to received light that provides the light to a downstream component or does not and instead misses the downstream component. In this way, the mirror each pass or extinguish light received at their respective positions. As will be discussed in greater detail below, such respective positions of the mirrors are mapped to an angle space and an illumination angle based on a known geometry between each position of each mirror in micromirror unit 202 and a light source. In this way, selected spatial frequencies may be deflected and/or attenuated, or may be provided to imaging optic 204 without attenuation.

Device 200 additionally includes imaging optic 204 which may be configured to receive the output of micromirror unit 202, and reflect the light to a downstream component, such as a target mask, or other illumination target. Imaging optic 204 may be a reflective mirror positioned such that the output of imaging optic 204 may be provided orthogonally to a surface plane of the illumination and lithography target, that may be a target mask. Moreover, imaging optic 204 may be configured to re-image a direct or intermediate source point, such as the light source, to an illumination plane where the target is positioned. As similarly discussed above, imaging optic 204 is configured to reflect the designated range of angles of light output by micromirror unit 202, and is further configured to not reflect the deflected and discarded angles or light. As shown in FIG. 2, micromirrors included in micromirror unit 202 have been configured to reflect a designated range of angles of light to imaging optic, which are then reflected to a downstream target. Moreover, some micromirrors have been configured to deflect another designated range of angles of light away from imaging optic 204 to extinguish those angles and not provide them to the downstream target. In this way, imaging optic 204 directs the designated range of angles of light to the target of device 200. In various embodiments, imaging optic 204 may be a spherical mirror, and aspheric mirror, or a combination of multiple mirrors.

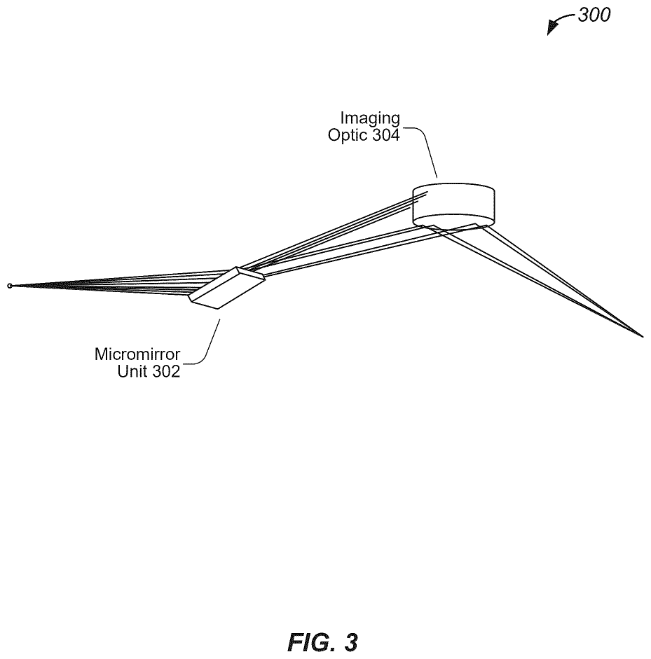

FIG. 3 illustrates another example of a device for coherence control, configured in accordance with some embodiments. As similarly discussed above, embodiments disclosed herein enable the implementation of a large range of coherence parameters used to control coherence of light received from a light source. Accordingly, a device, such as device 300, may include a spatial light modulator configured to implement coherence parameters to provide such coherence control.

As similarly discussed above, device 300 may include micromirror unit 302 which is configured to selectively reflect a designated range of angles of light received from a light source, and is further configured to deflect another designated range of angles of light. The output of micromirror unit 302 may be provided to imaging optic 304. As also discussed above, imaging optic 304 may be configured to re-image a direct or intermediate source point, such as the light source, to an illumination plane where the target is positioned. Accordingly, imaging optic 304 is configured to reflect the designated range of angles of light output by micromirror unit 302, and is further configured to not reflect the deflected and discarded angles or light.

As shown in FIG. 3, micromirror unit 302 may be configured as a glancing optic that is configured to have a relatively wide incidence angle relative to the light source. Moreover, imaging optic 304 may also be configured as a glancing optic and also have a relatively wide incidence angle relative to micromirror unit 302. In various embodiments, such a configuration enables a simplification of the reflective coatings used for micromirror unit 302 and imaging optic 304. In various embodiments, such a glancing optic is configured to have angles of incidence that fall below the critical angle for the material that imaging optic 304 is made of. For example, a coating may be used that is a single layer of material instead of the multilayer films that may be used for non-glancing EUV or soft-x-ray optics. More specifically, for a wavelength of 13.5 nm and a coating material of Ruthenium, the critical angle is about 20 degrees, where 90 degrees would be a normal angle of incidence. In this case, any angle from 0 to 20 degrees would be glancing configuration. Moreover, micromirror unit 302 may be coupled with a multiple bounce imaging optic, such as a Kirpatrick Baez glancing optic, or single or multi-element near-normal EUV optics.

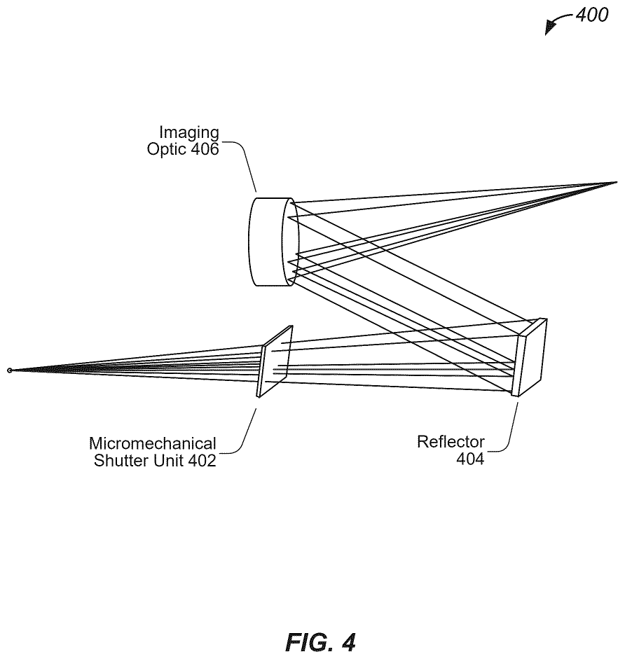

FIG. 4 illustrates an additional example of a device for coherence control, configured in accordance with some embodiments. As similarly discussed above, embodiments disclosed herein enable the implementation of a large range of coherence parameters used to control coherence of light received from a light source. In various embodiments, a device, such as device 400, may include a spatial light modulator that includes micromechanical shutters configured to implement coherence parameters to provide such coherence control.

In various embodiments, device 400 may include micromechanical shutter unit 402 which includes multiple micromechanical shutters that selectively transmit, or block light based on their respective actuation. For example, micromechanical shutter unit 402 may have arrays of beamlets that are gated by micromechanical shutters which may be raised to transmit light, and lowered to block light. As similarly discussed above, such actuation of the shutters may be controlled via a computer input and control software executed on a computing device or system. Accordingly, micromechanical shutter unit 402 may be configured to selectively transmit designated ranges of angles of light received from a light source, and is further configured to block another designated range of angles of light.

In various embodiments, the output of micromechanical shutter unit 402 is provided to reflector 404 which is configured to reflect the output to imaging optic 406, discussed in greater detail below. In various embodiments, reflector 404 may be a flat mirror configured to reflect EUV light. In some embodiments, reflector 404 may be configured to apply an optical power to operate in combination with imaging optic 406 to create an image of the source point at the location of the illumination point. In various embodiments, imaging optic 406 may be configured to re-image a direct or intermediate source point, such as the light source, to an illumination plane where the target is positioned. Accordingly, imaging optic 406 is configured to reflect the designated range of angles of light output by micromechanical shutter unit 402 and reflector 404, and is further configured to provide the reflected light to an illumination target.

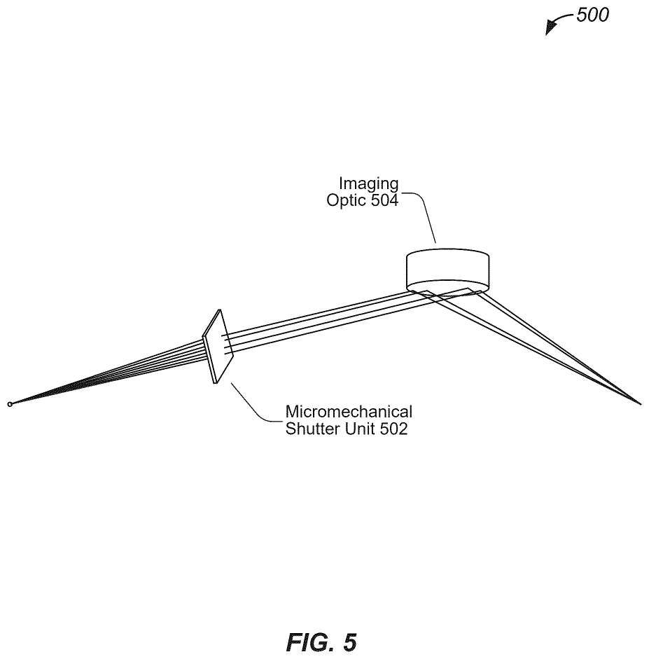

FIG. 5 illustrates another example of a device for coherence control, configured in accordance with some embodiments. As similarly discussed above, embodiments disclosed herein enable the implementation of a large range of coherence parameters used to control coherence of light received from a light source. In various embodiments, a device, such as device 500, may include a spatial light modulator that includes micromechanical shutters configured to implement coherence parameters to provide such coherence control. Moreover, device 500 may be configured in a glancing configuration.

As similarly discussed above, device 500 may include micromechanical shutter unit 502 which includes multiple micromechanical shutters that selectively transmit, or block light based on their respective actuation. As similarly discussed above, such actuation of the shutters may be controlled via a computer input and control software executed on a computing device or system. Accordingly, micromechanical shutter unit 502 may be configured to selectively transmit designated ranges of angles of light received from a light source, and is further configured to block another designated range of angles of light.

As shown in FIG. 5, the output of micromechanical shutter unit 502 may be provided to imaging optic 504 which is configured to reflect the output and re-image a direct or intermediate source point, such as the light source, to an illumination plane where the target is positioned. In various embodiments, imaging optic 504 is configured as a glancing optic, and thus provides a glancing configuration for the implementation of micromechanical shutter unit 502, and providing of a coherent optical output to a downstream target.

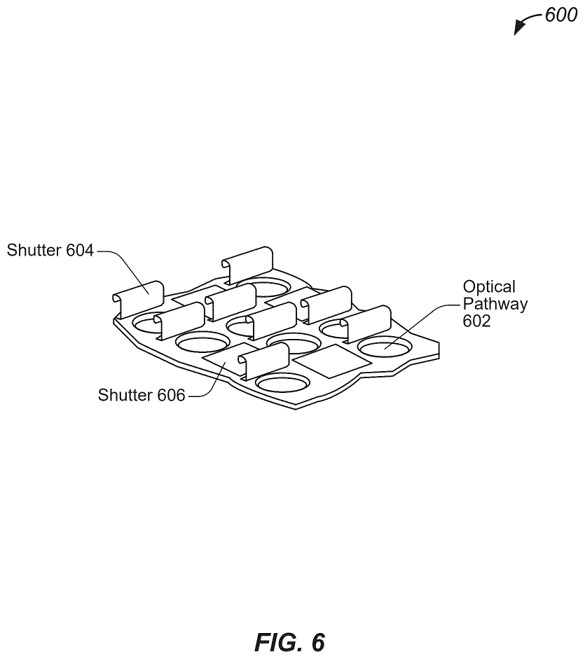

FIG. 6 illustrates an example of a micromechanical shutter unit, configured in accordance with some embodiments. As similarly discussed above, a micromechanical shutter unit, such as micromechanical shutter unit 600, may be configured to include multiple micromechanical shutters that selectively transmit, or block light based on their respective actuation. It will be appreciated that FIG. 6 illustrates a portion of shutter unit 600, and shutter unit 600 itself may include millions of shutters and associated optical pathways.

More specifically, micromechanical shutter unit 600 may include various optical pathways, such as optical pathway 602, that are configured to provide optical transmission paths for light received from a light source. Thus, optical pathway 602 may be a hole or other micro perforation in micromechanical shutter unit 600. As also discussed above, such optical pathways may be gated by micromechanical shutters, such as shutter 604. As shown in FIG. 6, such shutters may be positioned relative to an inlet of an associated optical pathway, and may be raised to transmit light, and lowered to block light. As shown in FIG. 6, shutter 604 has been raised to allow transmission of light, and shutter 606 has been lowered to block light. The raising and lowering of the shutters may be controlled via a computer input and control software executed on a computing device or system and via the application of electrical control signals in accordance with micro-electromechanical systems (MEMS) techniques. For simplicity, such electrical circuity is not shown in FIG. 6. Accordingly, micromechanical shutter unit 600 may be configured to selectively transmit designated ranges of angles of light received from a light source, and is further configured to block another designated range of angles of light.

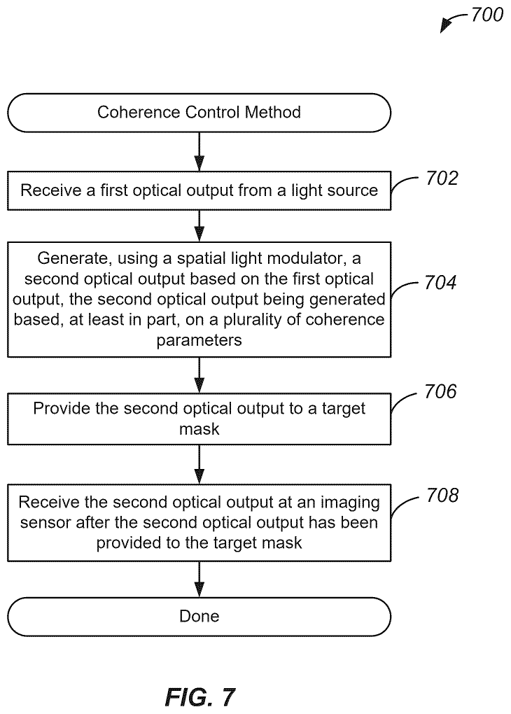

FIG. 7 illustrates an example of a method for coherence control, performed in accordance with some embodiments. As will be discussed in greater detail below, a method, such as method 700, may be performed to implement coherence parameters used to control coherence of light received from a light source and applied to a downstream target for illumination operations in the context of an EUV lithography system. For example, a spatial light modulator may be used to implement such coherence parameters in a manner that provides dynamic and programmable coherence control in various operational contexts, such as those including a brightness-limited light source.

Method 700 may perform operation 702 during which a first optical output may be received from a light source. As similarly discussed above, the light source may be an EUV light source. Moreover, the light source may be a brightness-limited light source. Accordingly, the light source may generate EUV light, and such light may be received at a component of an optical device that is configured as an illumination module in an EUV lithography system.

Method 700 may perform operation 704 during which a second optical output may be generated using a spatial light modulator and based on the first optical output. As similarly discussed above, the spatial light modulator may be included in the optical device, and may receive light from the light source. Moreover, the second optical output may be generated based, at least in part, on a plurality of coherence parameters. As similarly discussed above, the coherence parameters may identify a selected range of reflected angles that are used for illumination as well as a range of reflected angles that are discarded. Moreover, such selected ranges of angles may be applied across a two-dimensional mapping corresponding to the spatial light modulator. Accordingly, the second optical output may be generated based on such a mapping and implementation of such coherence parameters.

Method 700 may perform operation 706 during which the second optical output may be provided to a target mask. As similarly discussed above, the second optical output, having been generated based on the implementation of the coherence parameters, may be provided to a downstream target, and used to illuminate the downstream target. In one example, the downstream target is a target mask used in a lithography and fabrication process. Accordingly, the second optical output may be provided to the target mask to illuminate the target mask for operations associated with such processes.

Method 700 may perform operation 708 during which the second optical output may be received at an imaging sensor after the second optical output has been provided to the target mask. Accordingly, the second optical output may reflect off of the target mask, and may be received at the imaging sensor. As similarly discussed above, the imaging sensor may be configured to generate an image that may be sent to a computer system for subsequent image processing and analysis. The image of the target mask may then be used for assessment of uniformity as well as other features of the target mask in the context of a lithography and fabrication environment.

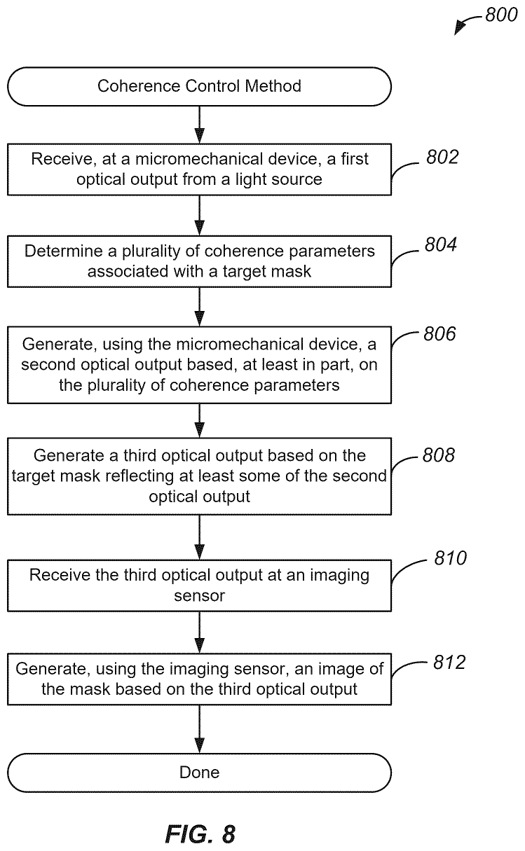

FIG. 8 illustrates another example of a method for coherence control, performed in accordance with some embodiments. As will be discussed in greater detail below, a method, such as method 800, may be performed to implement coherence parameters used to control coherence of light received from a light source and applied to a downstream target. More specifically, a micromechanical device may include multiple micromechanical elements that may be dynamically controlled to implement coherence parameters in a highly configurable and programmable manner.

Method 800 may perform operation 802 during which a first optical output may be received from a light source at a micromechanical device. As similarly discussed above, the light source may be an EUV light source. Moreover, the light source may be a brightness-limited light source. Accordingly, the light source may generate EUV light, and such light may be received at a component of an optical device that is configured as an illumination module in an EUV lithography system. In various embodiments, the first optical output may be received at a spatial light modulator that includes the micromechanical device.

Method 800 may perform operation 804 during which a plurality of coherence parameters associated with a target mask may be determined. As similarly discussed above, the coherence parameters may be received from a computing device or computing system, and may have been generated based on control software executed on such device or system. In various embodiments, the coherence parameters may identify angles at which micromirror elements should be positioned, or an amount to which a microshutter should be opened or closed. Such coherence parameters may be determined based on a mapping of an input or setting to such angles or and positions of each micromirror or microshutter included in the micromechanical device. In various embodiments, the input or setting may have been selected by an entity, such as a user or manufacturer, and may be mapped to corresponding actuation settings for the micromechanical elements based on a mapping that may have been determined by a manufacturer of the micromechanical device.

In one example, if annular illumination coherence settings are selected, the micromechanical device would be configured to set elements, such as mirrors or shutters, falling within the target inner radius of the annular setting to block the light. Moreover, elements falling within a range defined by a radius region greater than the target inner radius and smaller than the target outer radius would be set to pass light. Furthermore, elements falling within the radius region greater than the target outer radius would also be set to block the light.

Method 800 may perform operation 806 during which a second optical output may be generated based, at least in part, on the plurality of coherence parameters. More specifically, the second optical output may be generated using the micromechanical device to implement the determined coherence parameters. As similarly discussed above, the micromechanical device may be a micro-electro-mechanical systems (MEMS) device that is configured to include various micromechanical elements configured to be actuated based on a received input. The micromechanical device may be configured as a spatial light modulator, and may include various micromechanical mirrors that may be actuated to select or reject ranges of angles of reflected light based on coherence parameters. In some embodiments, the micromechanical device may include micromechanical shutters that are configured to be actuated and opened or closed to implement such coherence parameters.

Accordingly, during operation 806, micromechanical mirrors or micromechanical shutters may be actuated and positioned based on determined coherence parameters, and thus configure the micromechanical device to implement the coherence parameters. In this way, an output of the micromechanical device may include only the selected ranges of angles of light. In some embodiments, the output of the micromechanical device may be provided to an imaging optic, which may be a reflective mirror, that is used to reflect the output to a downstream component as the second optical output.

Method 800 may perform operation 808 during which a third optical output may be generated based on the target mask reflecting at least some of the second optical output. As similarly discussed above, the second optical output, having been generated based on the implementation of the coherence parameters, may be provided to a downstream target, and used to illuminate the downstream target. For example, the downstream target may be a target mask used in a lithography and fabrication process. Accordingly, the second optical output may be provided to the target mask to illuminate the target mask for operations associated with such processes. The reflected light may be a third optical output that also includes imaging information based on such reflecting.

Method 800 may perform operation 810 during which the third optical output may be received at an imaging sensor. As similarly discussed above, the imaging sensor may be a digital sensor such as a CCD or CMOS sensor that may be included in an imaging device or imaging system. Such a digital sensor may be configured to be sensitive to EUV light, and thus be configured to capture images of the target mask.

Method 800 may perform operation 812 during which an image of the mask may be generated based on the third optical output. As similarly discussed above, the imaging sensor may be configured to generate an image that may be sent to a computer system for subsequent image processing and analysis. For example, the digital sensor may capture pixel data based on the received third optical output, and an image may be generated and stored at an associated computer system. The image of the target mask may then be used for assessment of uniformity as well as other features of the target mask in the context of a lithography and fabrication environment.

Although the foregoing concepts have been described in some detail for purposes of clarity of understanding, it will be apparent that certain changes and modifications may be practiced within the scope of the appended claims. It should be noted that there are many alternative ways of implementing processes, systems, and apparatuses. Accordingly, the present embodiments are to be considered illustrative and not restrictive.

What is claimed is:

1. A system comprising:
a light source configured to generate a first optical output; and
an optical device configured to receive the first optical output, the optical device comprising:
a spatial light modulator configured to receive the first optical output from the light source, wherein the spatial light modulator comprises a micromechanical device configured to generate a second optical output based, at least in part, on the first optical output and a plurality of coherence parameters defining a plurality of angles of light to be included in the second optical output; and
an imaging optic configured to receive the second optical output from the spatial light modulator, and further configured to generate a third optical output provided to an imaging target.

2. The system of claim 1, wherein the plurality of coherence parameters identifies a first range of angles of light to be included in the second optical output, and wherein the plurality of coherence parameters further identifies a second range of angles of light to be removed from the second optical output.

3. The system of claim 1, wherein the micromechanical device comprises a plurality of micromechanical mirrors configured to be actuated based, at least in part, on the plurality of coherence parameters.

4. The system of claim 3, wherein each of the plurality of micromechanical mirrors comprises a coating configured to reflect extreme ultraviolet (EUV) light.

5. The system of claim 1, wherein the micromechanical device comprises a plurality of micromechanical shutters configured to be actuated based, at least in part, on the plurality of coherence parameters.

6. The system of claim 5, wherein each of the plurality of micromechanical shutters is configured to optically gate light provided to a corresponding optical pathway configured to transmit extreme ultraviolet (EUV) light.

7. The system of claim 1, wherein the light source is a brightness-limited extreme ultraviolet (EUV) light source.

8. The system of claim 6, wherein the light source has a first etendue that is larger than a second etendue of the optical device.

9. The system of claim 1, wherein the plurality of coherence parameters is determined based, at least in part, on an input received via a client machine associated with a user.

10. A device comprising:
a spatial light modulator configured to receive a first optical output from a light source, wherein the spatial light modulator comprises a micromechanical unit configured to generate a second optical output based, at least in part, on the first optical output and a plurality of coherence parameters defining a plurality of angles of light to be included in the second optical output; and
an imaging optic configured to receive the second optical output from the spatial light modulator, and further configured to generate a third optical output provided to an imaging target.

11. The device of claim 10, wherein the plurality of coherence parameters identifies a first range of angles of light to be included in the second optical output, and wherein the plurality of coherence parameters further identifies a second range of angles of light to be removed from the second optical output.

12. The device of claim 10, wherein the micromechanical unit comprises a plurality of micromechanical mirrors configured to be actuated based, at least in part, on the plurality of coherence parameters.

13. The device of claim 12, wherein each of the plurality of micromechanical mirrors comprises a coating configured to reflect extreme ultraviolet (EUV) light.

14. The device of claim 10, wherein the micromechanical unit comprises a plurality of micromechanical shutters configured to be actuated based, at least in part, on the plurality of coherence parameters.

15. The device of claim 14, wherein each of the plurality of micromechanical shutters is configured to optically gate light provided to a corresponding optical pathway configured to transmit extreme ultraviolet (EUV) light.

16. A method comprising:
receiving a first optical output from a light source;
generating, using a spatial light modulator, a second optical output, wherein the second optical output is generated by a micromechanical device included in the spatial light modulator and based, at least in part, on the first optical output and a plurality of coherence parameters defining a plurality of angles of light to be included in the second optical output;
providing the second optical output to imaging optic; and
generating, using the imaging optic, a third optical output being capable of being provided to an imaging target.

17. The method of claim 16, wherein the plurality of coherence parameters identifies a first range of angles of light to be included in the second optical output, and wherein the plurality of coherence parameters further identifies a second range of angles of light to be removed from the second optical output.

18. The method of claim 16, wherein the second optical output is generated by a plurality of micromechanical mirrors included in the micromechanical device, and based, at least in part, on the plurality of coherence parameters.

19. The method of claim 16, wherein the second optical output is generated by a plurality of micromechanical shutters included in the micromechanical device, and based, at least in part, on the plurality of coherence parameters.

20. The method of claim 16, wherein the light source is a brightness-limited extreme ultraviolet (EUV) light source.
